(19) United States
(12) Patent Application Publication
(10) Pub. No.: US 2015/0029666 A1
(43) Pub. Date: Jan. 29, 2015

(54) Power Conversion Apparatus

(71) Applicant: Hitachi Automotive Systems, Ltd., Hitachinaka-shi, Ibaraki (JP)

(72) Inventors: Masashi Kosuga, Hitachinaka-shi (JP); Hideyo Suzuki, Hitachinaka-shi (JP)

(73) Assignee: Hitachi Automotive Systems, LTD, Hitachinaka-shi, Ibaraki (JP)

(21) Appl. No.: 14/379,695

(22) PCT Filed: Feb. 15, 2013
(86) PCT No.: PCT/JP2013/053611

§ 371 Date: Aug. 19, 2014

(30) Foreign Application Priority Data
Mar. 30, 2012 (JP) 2012-078796

(51) Int. Cl. H02M 1/10; H02M 3/335; B60L 11/18; H05K 7/20

(52) U.S. Cl. CPC H02M 1/10; H05K 7/20218; H05K 7/20009; H02M 3/33569; B60L 11/1803; B60L 11/1814
USPC 361/699

(57) ABSTRACT

Disclosed is a downsized an integrated power-converter apparatus in which a plurality of power converter apparatuses is integrated, and to shorten a wiring connection distance in the power converter apparatus. The power-converter apparatus includes a power semiconductor module, a DC-to-DC converter, a capacitor module, a flow-path forming body for forming a flow path through which a refrigerant flows, a case, and a first DC connector for transmitting the DC current. The power semiconductor module is arranged in a position facing the DC-DC converter with the flow-path forming body interposed therebetween. The DC connector is arranged on one specified surface side of the case. The surface of the case is formed along an arrangement direction of the power semiconductor module, the flow-path forming body, and the DC-DC converter. The capacitor module is arranged between the surface of the case and the flow-path forming body, and is connected to the DC connector.

### TECHNICAL FIELD

The present invention relates to a power converter apparatus, and in particular to a plurality of power converter apparatuses for a hybrid vehicle, an electric vehicle, or a plug-in hybrid vehicle that has an engine and/or a motor as drive sources.

### BACKGROUND ART

A high-voltage storage battery and a low-voltage storage battery are mounted in an electric vehicle and a plug-in hybrid vehicle. The high-voltage storage battery supplies power to a power converter apparatus for driving a motor for driving a vehicle. The low-voltage storage battery supplies the power to auxiliary machines such as lamps and a radio of the vehicle. In such a vehicle, a DC-to-DC converter device is mounted that converts the power from the high-voltage storage battery to the low-voltage storage battery or converts the power from the low-voltage storage battery to the high-voltage storage battery.

It has been desired in such a vehicle to increase a ratio of a cabin to an overall volume of the vehicle as much as possible, so as to improve comfortability. Accordingly, it has also been desired to mount the power converter apparatus and the DC-to-DC converter device in the smallest space as possible on the outside of the cabin, especially within an engine room. In addition, it has been desired to arrange external connection terminals in one or two surfaces of each of the power converter apparatus and the DC-to-DC converter device as collectively as possible, so as to facilitate wiring to the connection terminals after the power converter apparatus and the DC-to-DC converter device are mounted in the vehicle. For example, PTL 1 below suggests securing favorable assembling workability for the external connection terminals by juxtaposing the DC-to-DC converter to a lateral surface of an inverter device and by arranging each of the external connection terminals in an upper surface of the DC-to-DC converter.

### CITATION LIST

### Patent Literature

PTL 1: JP-A-2004-304923

### SUMMARY OF INVENTION

### Technical Problem

The technical problem is to downsize a power converter apparatus. Meanwhile, the technical problem is to downsize an integrated power converter apparatus in which a plurality of the power converter apparatuses is integrated and to shorten a wiring connection distance in the power converter apparatus.

### Solution to Problem

In order to solve the above problem, an integrated power converter apparatus according to the invention includes: a power semiconductor module; a DC-to-DC converter for converting specified DC voltage to different DC voltage; a capacitor module for smoothing the DC voltage and supplying the smoothed DC voltage to the power semiconductor module and the DC-to-DC converter; a flow-path forming body for forming a flow path through which a refrigerant flows; a case for housing the power semiconductor module, the DC-to-DC converter, the capacitor module, and the flow-path forming body; and a first DC connector for transmitting a DC current. The power semiconductor module is arranged in a position facing the DC-to-DC converter with the flow-path forming body being interposed therebetween. The DC connector is arranged on a specified surface side of the case. The specified surface of the case is formed along an arrangement direction of the power semiconductor module, the flow-path forming body, and the DC-to-DC converter. The capacitor module is arranged between the specified surface of the case and the flow-path forming body and is connected to the DC connector.

### Advantageous Effects of Invention

It is possible by the invention to downsize a power converter apparatus. Meanwhile, it is possible to downsize an integrated power converter apparatus in which a plurality of the power converter apparatuses is integrated and to shorten a wiring connection distance in the power converter apparatus.

### BRIEF DESCRIPTION OF DRAWINGS

FIG. 1 is a system diagram of a system in a hybrid vehicle.

FIG. 2 is a circuit diagram of a configuration of an electric circuit shown in FIG. 1.

FIG. 3 is an external perspective view of a power converter apparatus 200.

FIG. 4 is an exploded perspective view of the power converter apparatus 200.

FIG. 5 is a cross-sectional view of an A-A cross section that is seen in an arrow direction in FIG. 3.

FIG. 6 is a cross-sectional view of a B-B cross section that is seen in an arrow direction in FIG. 3.

FIG. 7 (a) is a perspective view of a first power semiconductor module 300a of this embodiment. FIG. 7(b) is a schematic cross-sectional view of the first power semiconductor module 300a that is that is seen in an arrow direction of a cross section C.

FIG. 8 is a circuit diagram of a configuration of a built-in circuit of the first power semiconductor module 300a.

FIG. 9 is a view for showing a flow of DC current in the power converter apparatus 200.

FIG. 10 is a view for showing a flow of AC current in the power converter apparatus 200.

FIG. 11 is an exploded perspective view of external appearance of a capacitor module 500.

FIG. 12 is a perspective view of the external appearance of the capacitor module 500.

FIG. 13 is a circuit diagram of an example of a configuration of a built-in circuit in a DC-to-DC converter 100.

FIG. 14 is a circuit diagram of the configuration of the built-in circuit in the DC-to-DC converter 100.

FIG. 15 is a view for illustrating arrangement of components of the DC-to-DC converter 100.

FIG. 16 is a view for illustrating assembly of the DC-to-DC converter 100 to a case 10.

FIG. 17 is a view for illustrating a flow of power in the DC-to-DC converter 100.

### DESCRIPTION OF EMBODIMENTS

A power converter apparatus described in this embodiment, to which the invention is applied and on which a description will hereinafter be made, and a system using the apparatus solve various problems that are desirably solved for commercialization. One of the various problems solved by this embodiment is a problem related to shortening of a wiring connection distance in the power converter apparatus, which is described in Technical Problem above. In addition to an effect of shortening the wiring connection distance in the power converter apparatus, which is described in Advantageous Effects of Invention above, as well as the problems and the effects described above, various problems can be solved, and various effects can be achieved.

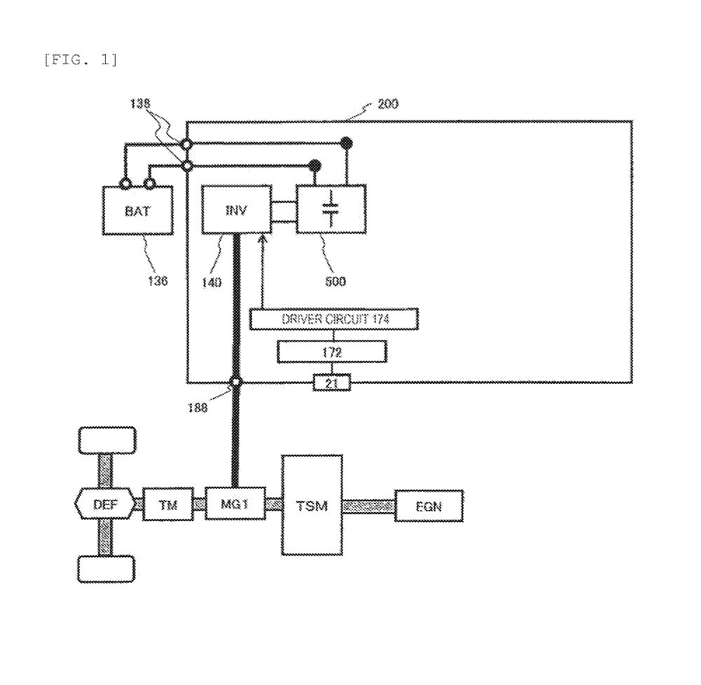

A description will hereinafter be made on an embodiment of the invention with reference to the drawings. FIG. 1 is a control block diagram of a hybrid vehicle (hereinafter described as the “HEV”).

An engine EGN and a motor generator MG1 generate traveling torque of the vehicle. Not only generating rotary torque, the motor generator MG1 also has a function to convert mechanical energy that is applied to the motor generator MG1 from the outside to electric power.

Output torque on an output side of the engine EGN is transmitted to the motor generator MG1 via a power dividing mechanism TSM. The rotary torque from the power dividing mechanism TSM or the rotary torque generated by the motor generator MG1 is transmitted to wheels via a transmission TM and a differential gear DEF. Meanwhile, in a travel during regenerative braking, the rotary torque is transmitted from the wheels to the motor generator MG1, so that AC power is generated on the basis of the supplied rotary torque. As will be described below, the thus-generated AC power is converted to DC power by a power converter apparatus 200 and stored in a high-voltage battery 136. The stored power is used again as traveling energy.

Next, the power converter apparatus 200 will be described. An inverter circuit 140 is electrically connected to the battery 136 via a DC connector 138, and the power is supplied and received between the battery 136 and the inverter circuit 140. When the motor generator MG1 is operated as a motor, the inverter circuit 140 generates the AC power on the basis of the DC power that is supplied from the battery 136 via the DC connector 138, and supplies the AC power to the motor generator MG1 via an AC connector 188. A configuration that includes the motor generator MG1 and the inverter circuit 140 is operated as a motor generator unit.

Here, the power converter apparatus 200 includes a capacitor module 500 for smoothing the DC power that is supplied to the inverter circuit 140.

The power converter apparatus 200 includes a connector for communication that receives a command from a superordinate control unit or sends data indicative of a state to the superordinate control unit. In the power converter apparatus 200, a control circuit 172 computes a control amount of the motor generator MG1 on the basis of a command input from the connector 21, further computes whether to operate the motor generator MG1 as the motor or a generator, generates a control pulse on the basis of a computation result, and supplies the control pulse to a driver circuit 174. Based on the supplied control pulse, the driver circuit 174 generates a drive pulse for controlling the inverter circuit 140.

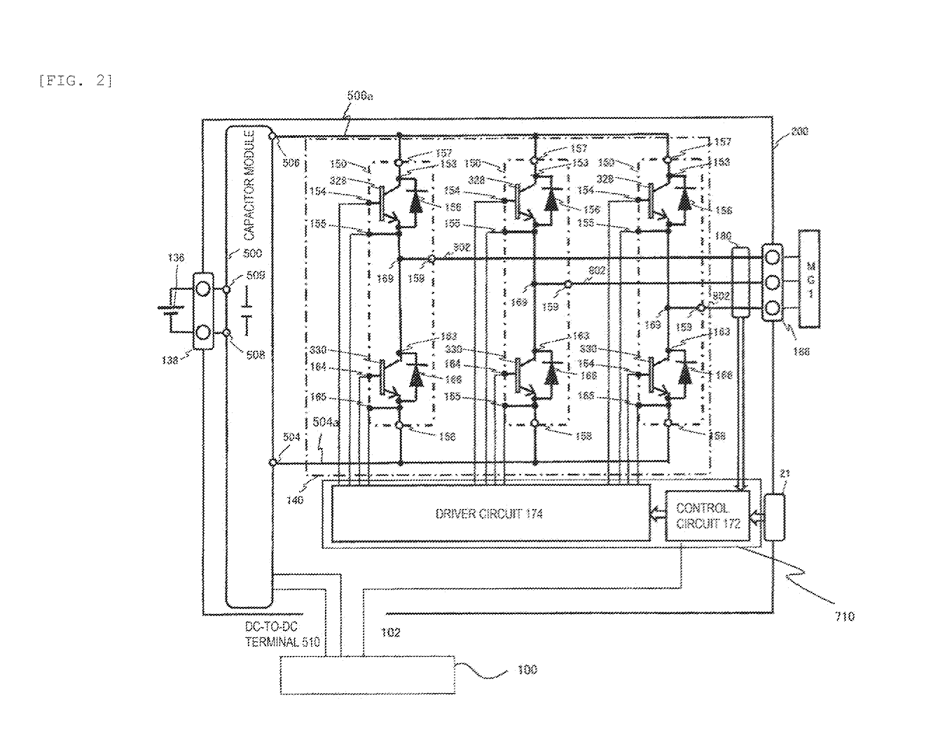

FIG. 2 is a circuit block diagram for illustrating a configuration of the inverter apparatus 200. In FIG. 2, an insulated gate bipolar transistor is used as a semiconductor element and is hereinafter abbreviated as the IGBT. A series circuit 150 of upper and lower arms is configured by an IGBT 328 and a diode 156 that are operated as the upper arm and an IGBT 330 and a diode 166 that are operated as the lower arm. The inverter circuit 140 includes the series circuits 150 so as to correspond to three phases of U-phase, V-phase, and W-phase of the AC power to be output.

These three phases respectively correspond to three phase windings of an armature winding of the motor generator MG1, which corresponds to a traveling motor in this embodiment. The series circuit 150 of the upper and lower arms for each of the three phases outputs AC current from an intermediate electrode 169 that is an intermediate portion of the series circuit. The intermediate electrode 169 is connected to an AC bus bar 802 as an AC power line to the motor generator MG1 through an AC terminal 159 and the AC connector 188.

A collector electrode 153 of the IGBT 328 in the upper arm is electrically connected to a capacitor terminal 506 on a positive electrode side of the capacitor module 500 via a positive electrode terminal 157. In addition, an emitter electrode of the IGBT 330 in the lower arm is electrically connected to a capacitor terminal 504 on a negative electrode side of the capacitor module 500 via a negative electrode terminal 158.

The driver circuit 174 supplies the drive pulse for controlling the IGBT 328 and the IGBT 330, which respectively constitute the upper arm and the lower arm of the series circuit 150 of the each phase, to the IGBT 328 and the IGBT 330 of the each phase. Based on the drive pulse from the driver circuit 174, the IGBT 328 and the IGBT 330 each perform a conductive or shutdown operation and convert the DC power supplied from the battery 136 to the three-phase AC power. The thus-converted power is supplied to the motor generator MG1.

The IGBT 328 includes the collector electrode 153, an emitter electrode 155 for a signal, and a gate electrode 154. Meanwhile, the IGBT 330 includes a collector electrode 163, an emitter electrode 165 for a signal, and a gate electrode 164. The diode 156 is electrically connected between the collector electrode 153 and the emitter electrode 155. Meanwhile, the diode 166 is electrically connected between the collector electrode 163 and the emitter electrode 165.

As a switching power semiconductor element, a metal-oxide-semiconductor field-effect transistor (hereinafter abbreviated as the MOSFET) may be used, and, in this case, the diode 156 and the diode 166 do not have to be provided. As the switching power semiconductor element, the IGBT is suited when DC voltage is relatively high, and the MOSFET is suited when the DC voltage is relatively low.

The capacitor module 500 includes the capacitor terminal 506 on the positive electrode side, the capacitor terminal 504 on the negative electrode side, a power supply terminal 509 on the positive electrode side, and a power supply terminal 508 on the negative electrode side. The high-voltage DC power from the battery 136 is supplied to the power supply terminal 509 on the positive electrode side and the power supply terminal 508 on the negative electrode side via the DC connector 138, and is then supplied from the capacitor terminal 506 on the positive electrode side and the capacitor terminal 504 on the negative electrode side of the capacitor module 500 to the inverter circuit 140.

On the other hand, the DC power that is converted from the AC power by the inverter circuit 140 is supplied from the capacitor terminal 506 on the positive electrode side and the capacitor terminal 504 on the negative electrode side to the capacitor module 500, is then supplied from the power supply terminal 509 on the positive electrode side and the power supply terminal 508 on the negative electrode side to the battery 136 via the DC connector 138, and is stored in the battery 136.

The control circuit 172 includes a microcomputer for arithmetic processing of switching timing of each of the IGBT 328 and the IGBT 330. Types of information input to the micom include a target torque value requested to the motor generator MG1, a current value supplied from the series circuit 150 to the motor generator MG1, and a magnetic pole position of a rotor in the motor generator MG1.

A control signal received from the superordinate control unit via the connector 21 is transmitted to a DC-to-DC converter 100 through an interface cable 102. In addition, the DC voltage received via the DC connector 138 is transmitted to the DC-to-DC converter 100 through a DC-to-DC terminal 510 of the capacitor module 500.

A first substrate 710 has the driver circuit 174, the control circuit 172, and a current sensor 180 mounted thereon.

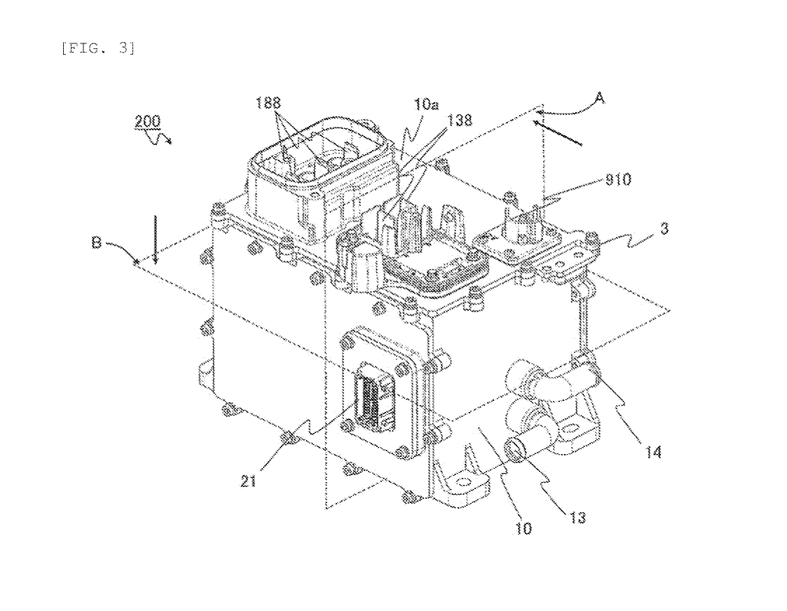

FIG. 3 is a perspective view of external appearance of the power converter apparatus 200. FIG. 4 is an exploded perspective view of the power converter apparatus 200 for illustrating an internal configuration of a case 10 of the power converter apparatus 200.

The power converter apparatus 200 according to this embodiment includes the DC connector 138, the AC connector 188, and a low voltage (LV) connector 910. The LV connector 910 transmits DC voltage that is different from the DC voltage transmitted through the DC connector 138 and that is lowered by the DC-to-DC converter 100. The DC connector 138, the AC connector 188, and the LV connector 910 are arranged in a specified plane 10a of the case 10. The plane 10a corresponds to an upper surface of the case 10 in this embodiment. In other words, the plane 10a is arranged such that an assembling worker can see the plane 10a from an opening side of a hood of the vehicle. Accordingly, after the power converter apparatus 200 is mounted in the vehicle, the DC connector 138, the AC connector 188, and the LV connector 910 can easily be connected. Thus, improved workability can be expected.

As shown in FIG. 4, the capacitor module 500 is arranged in an upper portion of the case 10. A plurality of first power semiconductor modules 300a to 300c that constitutes the inverter circuit 140 is arranged on one lateral surface side of the case 10. The first power semiconductor modules 300a to 300c are arranged substantially perpendicular to the capacitor module 500. The DC-to-DC converter 100 is arranged on another lateral surface side of the case 10.

In this embodiment, the first substrate 710 has the control circuit 172, the drive circuit 174, the current sensor 180, and the connector 21 mounted thereon. However, it is not essential that the first substrate 710 has the control circuit 172, the current sensor 180, and the connector 21 mounted thereon. These components may be provided separately from the first substrate 710, depending on a mounting space or the like. The first substrate 710 is arranged such that a mounting surface thereof is parallel to the first power semiconductor modules 300a to 300c.

An upper surface side cover 3 is fixed by a bolt so as to cover an opening in an upper surface direction of the case 10. In addition, a first lateral surface cover 904 is fixed by a bolt so as to cover an opening on a side that the first power semiconductor modules 300a to 300c are housed. The first lateral surface cover 904 is formed with a through hole 906 for penetrating the connector 21 in an area that faces the connector 21. Accordingly, since a wiring on the periphery of the connector 21 can be shortened, influence of noise can be reduced. In addition, since the connector 21 of a light electric system is arranged in the different surface from the surface in which the DC connector 138, the AC connector 188, and the LV connector 910 of heavy electric systems are arranged, the influence of the noise can be reduced.

A second lateral surface cover 905 is fixed by a bolt so as to cover an opening on a side that the DC-to-DC converter 100 is housed.

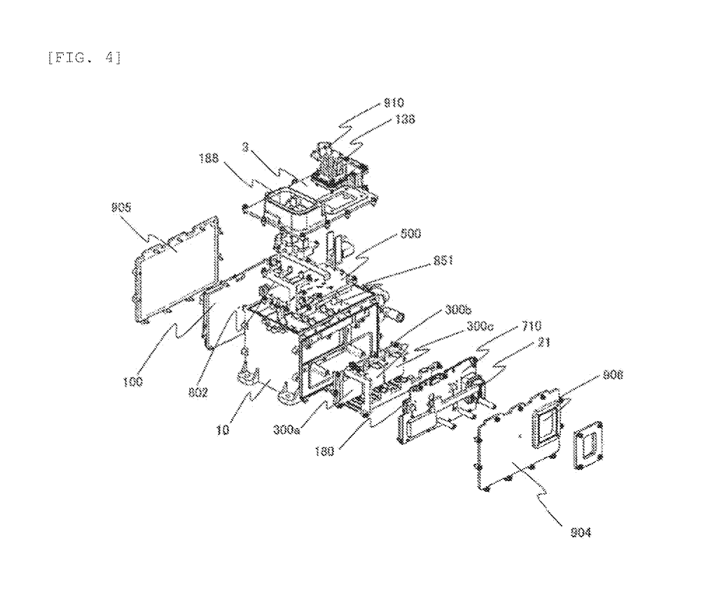

FIG. 5 is a view for facilitating understanding of FIG. 4, and is a cross-sectional view that is seen from an arrow direction of a cross section A in FIG. 3.

A flow-path forming body 19 is arranged slightly close to the DC-to-DC converter 100 from the vicinity of the center of the case 10, and is also arranged in a lower portion side of the case 10. The flow-path forming body 19 forms a first flow path 19a and a second flow path 19b. The first flow path 19a and the second flow path 19b are aligned along an arrangement direction D of the first power semiconductor modules 300a to 300c and the DC-to-DC converter 100. The first flow path 19a is arranged closer to the first power semiconductor modules 300a to 300c than the DC-to-DC converter 100, and is also arranged to face the first power semiconductor modules 300a to 300c. The second flow path 19b is arranged closer to the DC-to-DC converter 100 than the first power semiconductor modules 300a to 300c, and is also arranged to face the DC-to-DC converter 100.

The first power semiconductor modules 300a to 300c are arranged to contact the first flow path 19a. Meanwhile, the DC-to-DC converter 100 is arranged to contact the second flow path 19b. In other words, the first power semiconductor modules 300a to 300c are each arranged in a position to face the DC-to-DC converter 100 with the flow-path forming body 19 being interposed therebetween.

The DC connector 138 is arranged on the specified plane 10a side of the case 10. The specified plane 10a is formed along the arrangement direction D of the first power semiconductor modules 300a to 300c, the flow-path forming body 19, and the DC-to-DC converter 100. In other words, the specified plane 10a is formed parallel to the arrangement direction D. The capacitor module 500 is arranged between the specified plane 10a of the case 10 and the flow-path forming body 19, and is connected to the DC connector 138.

Accordingly, a wiring between the capacitor module 500 and the DC connector 138 can be shortened, and a wiring that transmits the DC power output from the capacitor module 500 can also be extremely shortened.

In addition, the capacitor module 500 is arranged to stretch over the first flow path 19a and the second flow path 19b.

Accordingly, the capacitor module 500, the first power semiconductor modules 300a to 300c, and the DC-to-DC converter 100 that are primary heat generating components of the power converter apparatus 200 in this embodiment can be cooled by a refrigerant. Thus, improved durability can be expected.

Furthermore, since a structure is adopted in which the first power semiconductor modules 300a to 300c, the capacitor module 500, and the DC-to-DC converter 100 are assembled to the case 10 from three different directions. Thus, an improved assembling property and an improved disassembling property can be expected.

Moreover, the first power semiconductor modules 300a to 300c and the DC-to-DC converter 100 are each assembled from a lateral surface direction of a longitudinal side that is adjacent to the upper surface of the case 10 in which an external interface is arranged. Consequently, a connection distance between the first power semiconductor modules 300a to 300c and the AC connector 188 and a connection distance between the DC-to-DC converter 100 and the LV connector 910 can be shortened.

Accordingly, an electric connection distance in the power converter apparatus 200 can be shortened. Thus, improvement in downsizing, weight reduction, and noise resistance performance can be expected.

The case 10 has a first recessed section 850 in which the first power semiconductor modules 300a to 300c are housed. A bottom surface of the first recessed section 850 is formed by the flow-path forming body 19, and a portion of a lateral surface thereof is formed by a wall 850a for housing the capacitor module 500.

The case 10 has a second recessed section 851 for housing the capacitor module 500. A bottom surface of the second recessed section 851 is formed by the flow-path forming body 19 and the wall 850a, and a portion of a lateral surface thereof is formed by a wall 851a for housing the first substrate 710.

A wall 851b forms both of a space for housing the capacitor module 500 and a space for housing the DC-to-DC converter 100.

The first substrate 710 is arranged in a position to face the bottom surface of the first recessed section 850 with the first power semiconductor modules 300a to 300c being interposed therebetween. Furthermore, the first substrate 710 is supported by the wall 851a, and is attached to close the first recessed section 850 in which the first power semiconductor modules 300a to 300c are housed.

Accordingly, the first substrate 710 can thermally be connected to the flow-path forming body 19 via the wall 850a or the wall 851a, and thus the first substrate 710 can be cooled. In addition, as shown in FIG. 4, a space for mounting the current sensor 180 can easily be secured between the first power semiconductor modules 300a to 300c and the first substrate 710. Thus, since the internal space of the power converter apparatus 200 can effectively be used without being wasted, the improvement in the downsizing and the weight reduction can be expected.

The first recessed section 850 and the second recessed section 851 are different in size from each other correspondence with the components housed therein. Accordingly, erroneous assembly can easily be detected during assembly work, and thus the erroneous assembly can be prevented. In this embodiment, the first recessed section 850 on the first power semiconductor modules 300a to 300c side is formed deeper than the second recessed section 851.

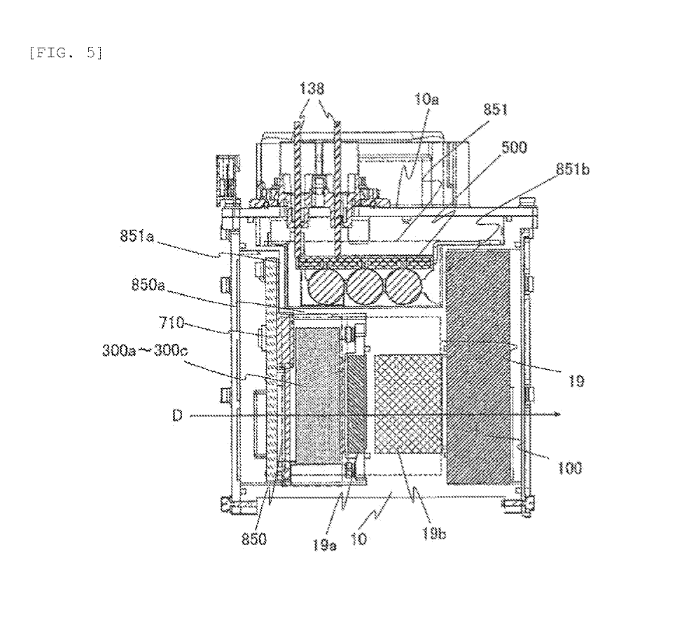

FIG. 6 is a view for illustrating the flow-path forming body 19, and is a cross-sectional perspective view that is seen from an arrow direction of a cross section B in FIG. 3.

An inlet pipe 13, into which the refrigerant flows, and an outlet pipe 14, from which the refrigerant flows out, are arranged on a same lateral surface of the case 10. The flow-path forming body 19 forms a first opening section 19c and a second opening section 19d. The first opening section 19c is formed in a direction in which the first power semiconductor modules 300a to 300c are arranged, and the second opening section 19d is formed in a direction in which the DC-to-DC converter 100 is arranged.

The first opening section 19c is sealed by a base board 301 on which the first power semiconductor modules 300a to 300c are mounted. The base board 301 makes direct contact with the refrigerant that flows through the first flow path 19a. In addition, the base board 301 has a fin 302a that is formed to face the first power semiconductor module 300a, a fin 302b that is formed to face the first power semiconductor module 300b, and a fin 302c that is formed to face the first power semiconductor module 300c.

The refrigerant flows through the inlet pipe 13 in a flow direction 417 shown by an arrow and then flows through the first flow path 19a, which is formed along the longitudinal side of the case 10, as shown by a flow direction 418. In addition, as shown by a flow direction 421, the refrigerant flows through a flow path section that is formed along a short side of the case 10 in the flow direction 421, thereby forming a return flow path. Furthermore, as shown by a flow direction 422, the refrigerant flows through the second flow path 19b that is formed along the longitudinal side of the case 10. The second flow path 19b is provided in a position facing the first flow path 19a. Moreover, as shown by a flow direction 423, the refrigerant flows through the outlet pipe 14 and flows out therefrom. In this embodiment, water is most suited as the refrigerant. However, since a substance other than water, such as the air, can be used, it will hereinafter be described as the refrigerant.

Since the first flow path 19a and the second flow path 19b are formed to face each other along the longitudinal side of the case 10, they are configured to be easily manufactured by aluminum forging.

A description will be made on configurations of the first power semiconductor modules 300a to 300c that are used in the inverter circuit 140 by using FIG. 7. The first power semiconductor module 300a is provided with the series circuit 150 of the U-phase. The first power semiconductor module 300b is provided with the series circuit 150 of the V-phase. The first power semiconductor module 300c is provided with the series circuit 150 of the W-phase. Since the first power semiconductor modules 300a to 300c each have the same structure, the structure of the first power semiconductor module 300a will be described as a representative example.

In FIG. 7, a signal terminal 325U corresponds to the gate electrode 154 and the emitter electrode 155 for a signal that are disclosed in FIG. 2. A signal terminal 325L corresponds to the gate electrode 164 and the emitter electrode 165 that are disclosed in FIG. 2. In addition, a DC positive electrode terminal 315B is same as the positive electrode terminal 157 that is disclosed in FIG. 2, and a DC negative electrode terminal 319B is same as the negative electrode terminal 158 that is disclosed in FIG. 2. Furthermore, an AC terminal 320B is same as the AC terminal 159 that is disclosed in FIG. 2.

FIG. 7(a) is a perspective view of the first power semiconductor module 300a of this embodiment. FIG. 7(b) is a schematic cross-sectional view of the first power semiconductor module 300a that is seen in an arrow direction of a cross section C.

As shown in FIG. 7(a) and FIG. 7(b), in the first power semiconductor module 300a, the semiconductor elements (the IGBT 328, the IGBT 330, the diode 156, and the diode 166) for constituting the series circuit 150 are covered by an integrally molded resin member 350. The resin member 350 is configured of a high Tg transfer resin, for example, and is integrally and seamlessly molded.

The DC positive electrode terminal 315B and the DC negative electrode terminal 319B that are connected to the capacitor module 500, and the AC terminal 320B of the U, V, and W-phases that is connected to the motor are projected from one lateral surface of the resin member 350. In addition, the signal terminal 325U and the signal terminal 325L are projected from a lateral surface that faces the lateral surface from which the positive electrode terminal 315B and the like are projected. The resin member 350 has a semiconductor module section that includes a wiring.

As shown in FIG. 7(b), in the semiconductor module section, the IGBT 328, the IGBT 330, the diode 156, the diode 166, and the like of the upper and lower arms are provided on an insulating substrate 334, and protected by the resin member 350 described above. The insulating substrate 334 may be a ceramic substrate, or may be a thinner insulating sheet or a SiN.

The DC positive electrode terminal 315B and the DC negative electrode terminal 319B respectively have a connection end 315k and a connection end 319k for connection with a circuit wiring pattern 334k on the insulating substrate 334. In addition, a tip of each of the connection end 315k and the connection end 319k is bent to form a joining surface to the circuit wiring pattern 334k. The connection end 315k and the connection end 319k are each connected to the circuit wiring pattern 334k via solder or the like, or by directly subjecting metals to ultrasonic welding.

The insulating substrate 334 is fixed onto a metal base 304 via solder 337a, for example. The solder 337a is joined to a solid pattern 334r. The IGBT 328 for the upper arm and the diode 156 for the upper arm as well as the IGBT 330 for the lower arm and the diode 166 for the lower arm are fixed to the circuit wiring pattern 334k by solder 337b. The circuit wiring pattern 334k and the semiconductor element are connected by a bonding wire 371.

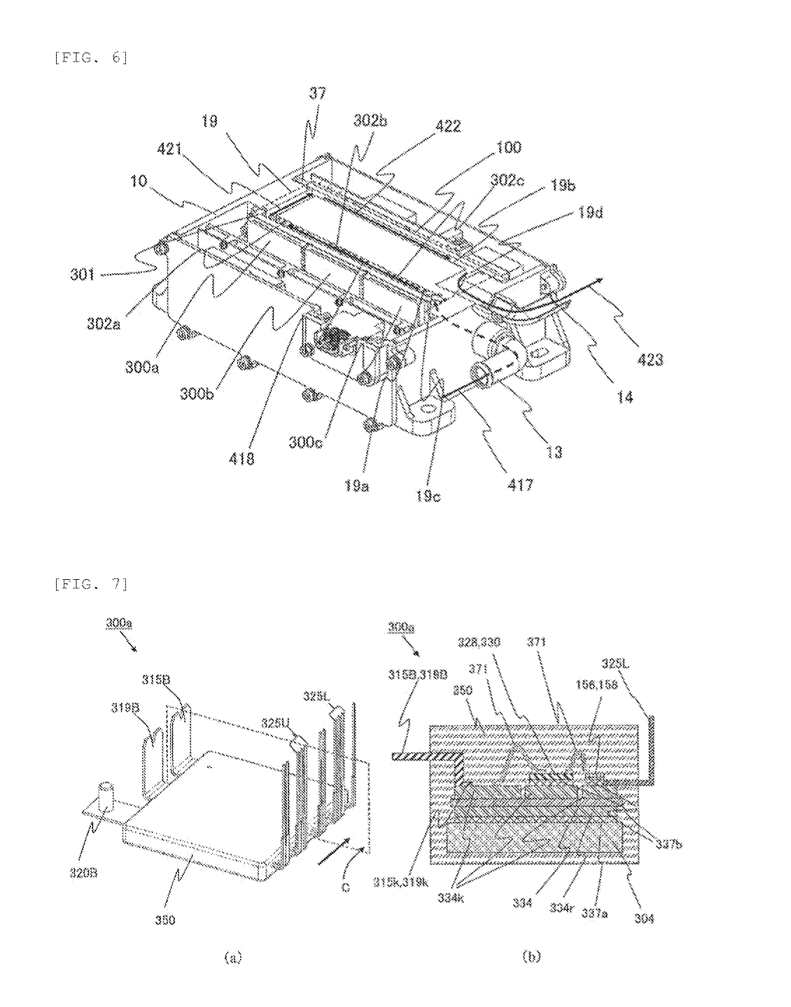

FIG. 8 is a circuit diagram of a configuration of an internal circuit of the first power semiconductor module 300a. The collector electrode of the IGBT 328 on the upper arm side is connected to a cathode electrode of the diode 156 on the upper arm side via a conductor plate 315. The DC positive electrode terminal 315B is connected to the conductor plate 315. The emitter electrode of the IGBT 328 and an anode electrode of the diode 156 on the upper arm side are connected via a conductor plate 318. The three signal terminals 325U are connected in parallel to the gate electrode 154 of the IGBT 328. A signal terminal 336U is connected to the emitter electrode 155 for a signal of the IGBT 328.

Meanwhile, a collector electrode of the IGBT 330 on the lower arm side is connected to a cathode electrode of the diode 166 on the lower arm side via a conductor plate 320. The AC terminal 320B is connected to the conductor plate 320. The emitter electrode of the IGBT 330 is connected to an anode electrode of the diode 166 on the lower arm side via a conductor plate 319. The DC negative electrode terminal 319B is connected to the conductor plate 319. The three signal terminals 325L are connected in parallel to the gate electrode 164 of the IGBT 330. A signal terminal 336L is connected to the emitter electrode 165 for a signal of the IGBT 330.

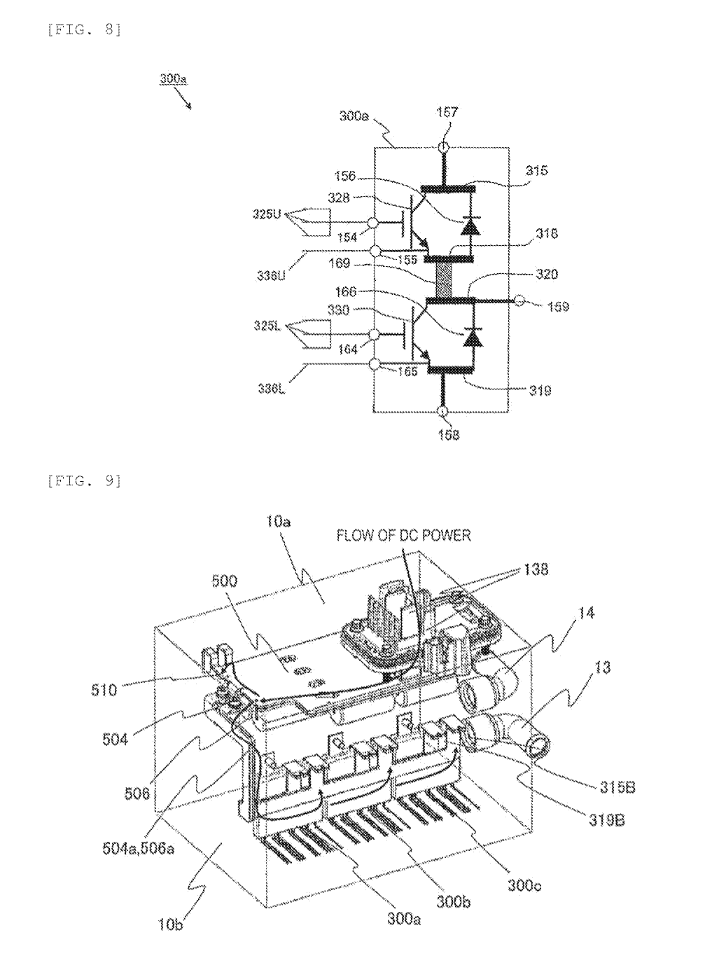

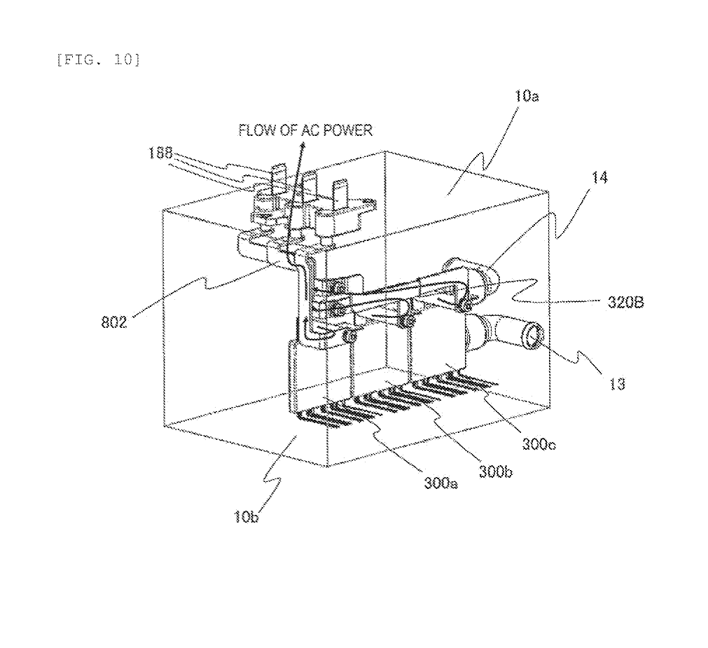

A description will be made on a flow of the current in the power converter apparatus 200 of this embodiment by using FIG. 9 and FIG. 10. FIG. 9 is a perspective view of a flow of the DC power in the power converter apparatus 200 of this embodiment. The components that are not related to the flow of the DC power are not shown. The DC power supplied from the battery 136 is input to the power converter apparatus 200 via the DC connector 138.

The DC power, which is input from the DC connector 138, passes through the capacitor module 500 to be smoothed, and is then supplied to the capacitor terminals 504, 506 for transmitting the DC power to the first power semiconductor modules 300a to 300c and to the DC-to-DC terminal 510 for transmitting the DC power to the DC-to-DC converter 100. The flow of the power after reaching the DC-to-DC converter 100 will be described below.

After passing through the capacitor terminals 504, 506, the DC power is input from the DC positive electrode terminal 315B and the DC negative electrode terminal 319B in each of the first power semiconductor modules 300a to 300c to the inverter circuit 140 in each of the first power semiconductor modules 300a to 300c via DC bus bars 504a and 506a.

The DC bus bar 504a and the DC bus bar 506a are configured in a laminated state via an insulating member. In addition, the DC bus bar 504a and the DC bus bar 506a are arranged along a plane 10b that is different from the surface in which the first power semiconductor modules 300a to 300c are arranged and the plane 10a in which the DC connector 138 is arranged. The plane 10b faces the surface on which the inlet pipe 13 and the outlet pipe 14 are arranged. Accordingly, the plane 10b can effectively be used, which leads to the downsizing of the power converter apparatus 200. In addition, the components in the power converter apparatus 200 can be protected from electromagnetic noise that is radiated from the DC bus bar 504a and the DC bus bar 506a.

FIG. 10 is a perspective view of a flow of the AC power in the power converter apparatus 200 of this embodiment. The components that are not related to the flow of the AC power are not shown.

The power that is converted to AC is transmitted from the AC terminal 320B of each of the first power semiconductor modules 300a to 300c to the AC connector 188 via the AC bus bar 802. The AC power that is output from the AC connector 188 is transmitted to the motor generator MG1 to generate the traveling torque of the vehicle.

Here, an example of the flow is shown in which the power stored in the battery 136 reaches the motor generator MG1. In a case where the motor generator MG1 is operated as the generator that converts the mechanical energy applied from the outside to the power and stores the power in the battery 136, the power is transmitted in a flow that is opposite from the flow in the above description.

The AC bus bar 802 is arranged along the plane 10b, which is different from the surface in which the first power semiconductor modules 300a to 300c are arranged and the plane 10a in which the DC connector 138 is arranged. Accordingly, the plane 10b can effectively be used, which leads to the downsizing of the power converter apparatus 200. In addition, the components in the power converter apparatus 200 can be protected from the electromagnetic noise that is radiated from the AC bus bar 802.

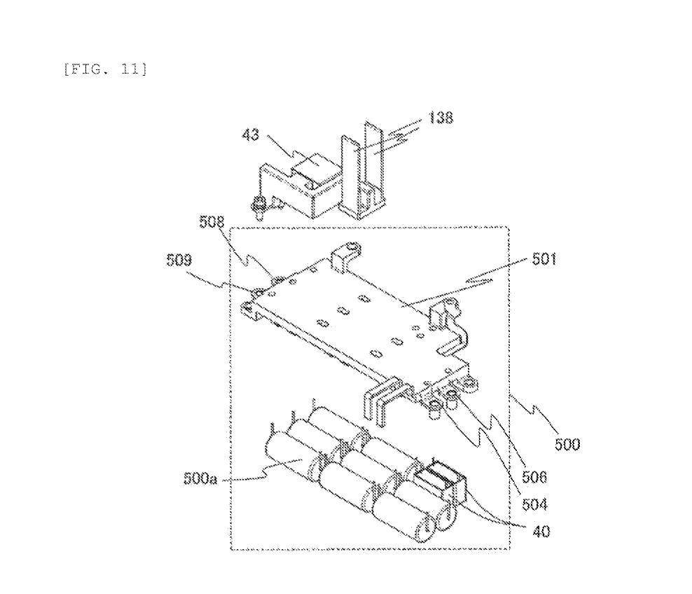

FIG. 11 and FIG. 12 are views for illustrating the capacitor module 500. FIG. 11 is an exploded perspective view in which the capacitor module 500 and the DC connector 138 are shown. FIG. 12 is a perspective view in which resin components of the DC connector 138 and the capacitor module 500 are not shown to facilitate understanding.

The capacitor module 500 is formed of a capacitor bus bar 501, a plurality of capacitor elements 500a, and a Y-capacitor 40. The plurality of capacitor elements 500a is connected in parallel to the capacitor bus bar 501. The capacitor module 500 is configured by one or more of the capacitor elements 500a.

The Y-capacitor 40 is configured by a capacitor that has a plurality of terminals and in which one of the plural terminals is electrically grounded. The Y-capacitor 40 is provided as a measure against the noise and is connected in parallel to the plurality of capacitor elements 500a.

The plurality of capacitor elements 500a is connected to the capacitor bus bar 501. The capacitor bus bar 501 is formed of a positive electrode bus bar 501P, a negative electrode bus bar 501N, and a capacitor bus bar resin 501M. In this embodiment, a configuration is adopted in which the positive electrode bus bar 501P and the negative electrode bus bar 501N are laminated and integrally molded by the capacitor bus bar resin 501M. However, a configuration may be adopted in which the positive electrode bus bar 501P and the negative electrode bus bar 501N are laminated with an insulating sheet being interposed therebetween.

Aback side of the capacitor bus bar resin 501M is shaped to follow shapes of the capacitor elements 500a. In addition, the bottom of the first recessed section 850 described above is also provided with a shape that follows the shapes of the capacitor elements 500a.

The plurality of capacitor elements 500a is fixed by being interposed between the capacitor bus bar resin 501M and the first recessed section 850 due to the shapes provided in the capacitor bus bar resin 501M and the bottom of the first recessed section 850.

The positive electrode bus bar 501P and the negative electrode bus bar 501N are each provided with a hole through which a terminal on each of the positive electrode side and the negative electrode side of each of the plurality of capacitor elements 500a penetrates. Since the plurality of capacitor elements 500a is welded to the bus bar on the positive electrode side and the bus bar on the negative electrode side in a state that the terminals of the capacitor elements 500a penetrate the bus bars, the plurality of capacitor elements 500a is connected to the bus bar on the positive electrode side and the bus bar on the negative electrode side.

The DC connector 138 has one end provided with a terminal that is connected to a connector led to the battery 136, and has another end that is connected to the power supply terminal 509 on the positive electrode side and the power supply terminal 508 on the negative electrode side of the capacitor module 500. In addition, an X-capacitor 43 is provided as a measure against the noise at the center of the DC connector.

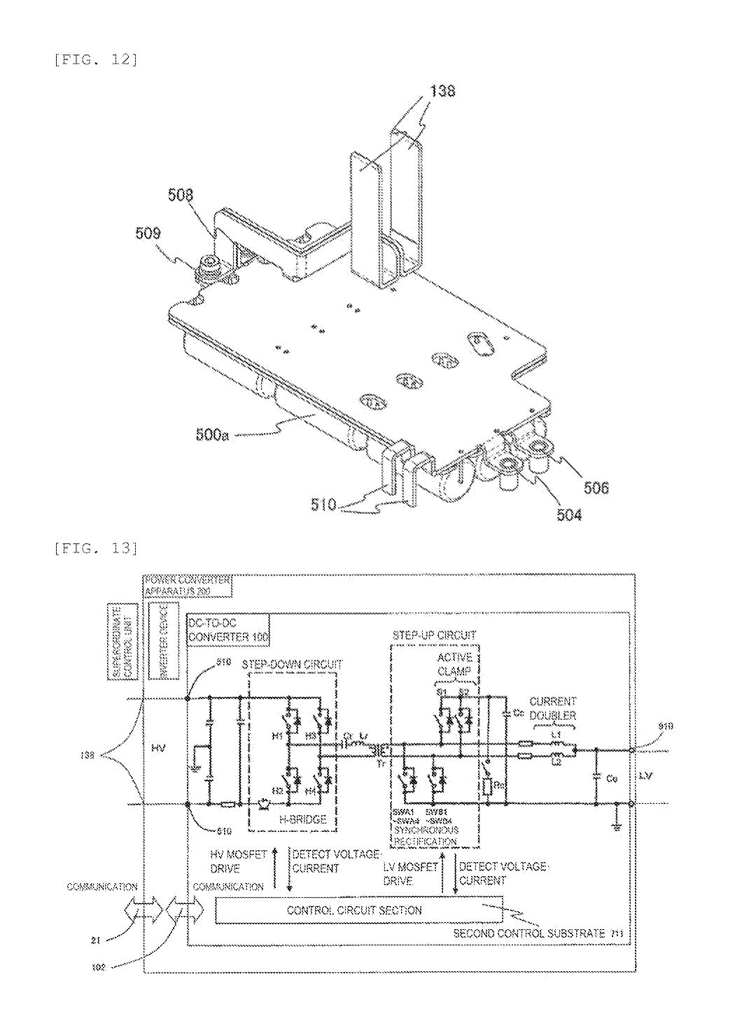

Next, a description will be made on the DC-to-DC converter 100. FIG. 13 and FIG. 14 are circuit configuration diagrams of the DC-to-DC converter 100.

An example of FIG. 13 is a bidirectional DC-to-DC converter that increases and lowers the voltage. Thus, a step-down circuit (an HV circuit) on a primary side and a step-up circuit on a secondary side (an LV circuit) each have a configuration of synchronous rectification instead of diode rectification. In addition, in order to generate the high output by HV/LV conversion, a large current part is adopted for a switching element, and a smoothing coil is enlarged.

More specifically, each of the HV/LV sides adopts a configuration of an H-bridge type synchronous rectification switching circuit (H1 to H4) that uses the MOSFET having a recovery diode. For switching control, an LC series resonance circuit (Cr, Lr) is used for zero cross switching at a high switching frequency (100 kHz), so as to improve conversion efficiency and reduce thermal loss. In addition, an active clamp circuit is provided to reduce loss that is caused by the circulating current during a step-down operation. Furthermore, generation of surge voltage during switching is suppressed to lower withstand voltage of the switching element. Accordingly, the withstand voltage of the circuit component is lowered, and thus the device is downsized.

Furthermore, in order to secure the high output on the LV side, a full-wave rectifying current doubler type is adopted. In order to generate the high output, a plurality of the switching elements is simultaneously operated in parallel to secure the high output. In the example of FIG. 13, four elements of SWA1 to SWA4 and four elements of SWB1 to SWB4 are arranged in parallel. Moreover, two circuits that include the switching circuits and small smoothing reactors (L1, L2) are arranged in parallel in a symmetrical manner to generate the high output. The small reactors are arranged in the two circuits just as described. Thus, compared to a case where a single large reactor is arranged, the DC-to-DC converter as a whole can be downsized.

In a lower portion of the circuit configuration diagram in FIG. 13, a second substrate 711 is shown that has a driver circuit and an operation detection circuit for each of the step-down circuit and the step-up circuit, and a control circuit section with a function to communicate with the superordinate control unit through an inverter device mounted thereon. The communication with the superordinate control unit is performed through the inverter device. Accordingly, a communication interface with the superordinate control unit can be shared in both of a case where the inverter device and the DC-to-DC converter are integrated and a case where the inverter device is separately provided.

In an example of FIG. 14, as in the example of FIG. 13, the step-down circuit (the HV circuit) on the primary side is configured as a full-bridge circuit, and the LV circuit on the secondary side is configured as the diode rectification circuit. In this embodiment, a circuit configuration in FIG. 14 is adopted.

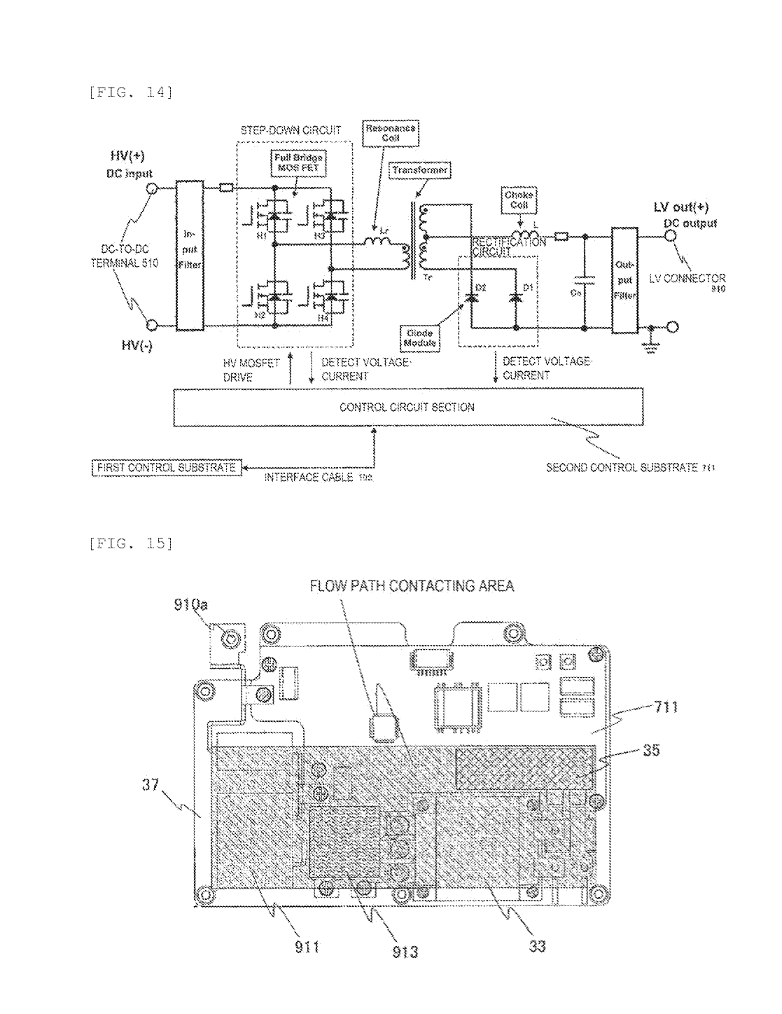

FIG. 15 is a view for illustrating arrangement of the components in the DC-to-DC converter 100, and is a plan view that only shows the DC-to-DC converter 100.

As shown in FIG. 15, the circuit components of the DC-to-DC converter 100 are attached to a base board 37 that is made of metal (aluminum die cast, for example). More specifically, a primary transformer 33, a second power semiconductor module 35 in which the switching elements H1 to H4 are mounted, the second substrate 711, a capacitor, a thermistor, and the like are mounted. The second substrate 711 has an input filter, an output filter, the microcomputer, a transformer, a connector that connects the interface cable 102 for the communication with the first substrate 710, and the like mounted thereon. Primary heat generating components are the primary transformer 33, an inductor element 34, and the second power semiconductor module 35.

Correspondence with the circuit diagram in FIG. 14 is described. The primary transformer 33 and the inductor element 34 respectively correspond to a transformer Tr and the reactors L1, L2 of the current doubler.

The second substrate 711 is fixed on a plurality of support members that is projected upward from the base board 37. In the second power semiconductor module 35, the switching elements H1 to H4 are mounted on a metal substrate that is formed with a pattern, and a back surface side of the metal substrate is fixed so as to be tightly adhered to a front surface of the base board 37.

As described above, all of the circuit components of the DC-to-DC converter 100 in this embodiment are attached to the base board 37. Accordingly, the DC-to-DC converter 100 can be attached as a single module to the case 10. Thus, the improved assembling workability of the power converter apparatus 200 can be expected.

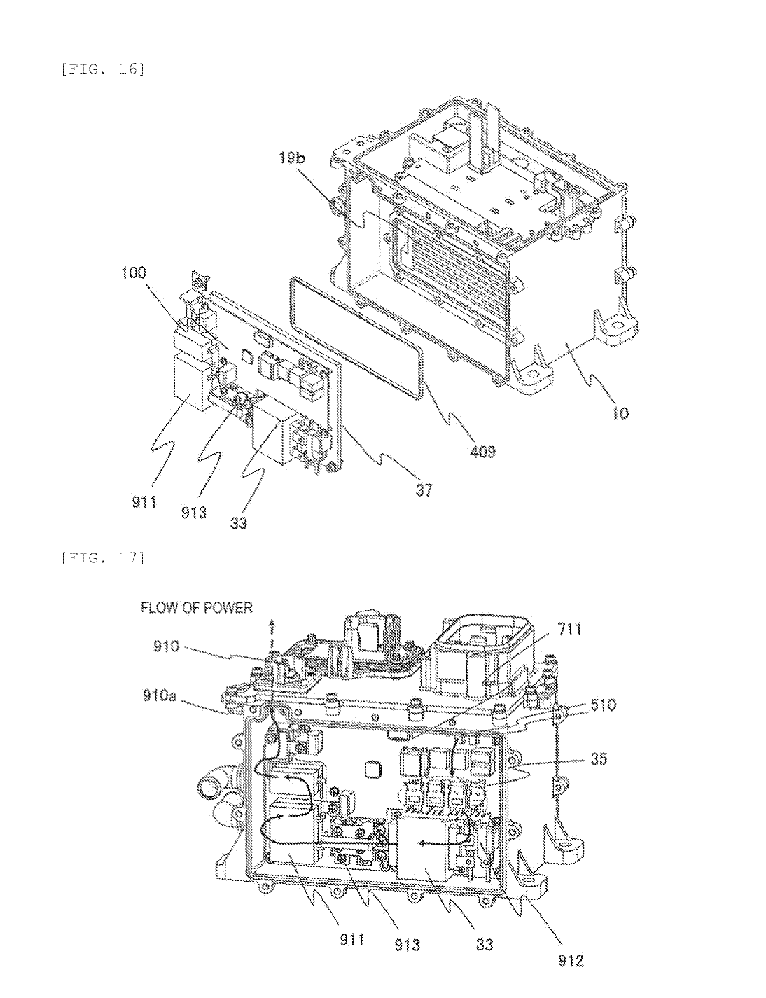

FIG. 16 is an exploded perspective view of the DC-to-DC converter 100.

The base board 37 of the DC-to-DC converter 100 is attached to the case 10 in a manner to seal the second flow path 19b that is housed in the case 10. Accordingly, the base board 37 forms a portion of a wall of a cooling path 19. A seal member 409 is provided between the case 10 and the base board 37, thereby retaining airtightness.

In addition, the base board 37 is arranged on a bottom surface of a housing space for the DC-to-DC converter 100 in the case 10, and a portion of the base board 37 seals an opening that is connected to the second flow path 19b. The heat generating components, such as the primary transformer 33, a diode 913, a choke coil 911, are arranged in an area in the base board 37 that faces the second flow path 19b. Accordingly, these heat generating components are efficiently cooled by the refrigerant that flows through the second flow path 19b.

Thus, a temperature increase of the MOSFET in the second power semiconductor module 35 can be suppressed, and consequently, the performance of the DC-to-DC converter 100 can easily be exerted. In addition, a temperature increase of a winding of the primary transformer 33 can be suppressed, and consequently, the performance of the DC-to-DC converter 100 can easily be exerted.

FIG. 17 is a view of a flow of the power in the DC-to-DC converter 100. The DC power that is supplied from the DC-to-DC terminal 51 of the capacitor module 500 is input to the second power semiconductor module 35 and lowered to the specified voltage. Here, since the second power semiconductor module 35 is arranged between the second substrate 711 and the base board 37, it cannot be seen under a normal circumstance. However, the second power semiconductor module 35 is shown to facilitate understanding. The power, the voltage of which is lowered by the second power semiconductor module 35, passes through a coil 912 and reaches the primary transformer 33.

Then, after the power that is output from the primary transformer 33 is rectified by the diode 913, the power reaches a connection terminal 910a with the LV connector 910 via the choke coil 911. Furthermore, due to fixation by a bolt at the connection terminal 910a to the LV connector 910, the power that is converted in the DC-to-DC converter 100 is output to the outside of the power converter apparatus 200.

In this embodiment, as described above, the DC-to-DC converter 100 is assembled from the lateral surface direction of a longitudinal direction that is adjacent to the upper surface of the case 10 in which the LV connector 910 is arranged. Thus, it is possible to shorten a connection distance between the connection terminal 910a of the DC-to-DC converter 100 and the LV connector 910.

What has been described so far is merely one example, and a corresponding relationship between the descriptions of the above embodiment and the claims causes no limitation or restriction on comprehension of the invention. For example, in the embodiment described above, the example of the power converter apparatus that is mounted in the vehicle such as a PHEV or an EV is described. However, the invention is not limited thereto but can be applied to a power converter apparatus that is used in a construction machinery vehicle and the like.

### REFERENCE SIGNS LIST

3: upper surface side cover
10: case
10a, 10b: plane
13: inlet pipe
14: outlet pipe
19: flow-path forming body
19a: first flow path
19b: second flow path
19c: first opening section
19d: second opening section
21: connector
33: primary transformer
35: second power semiconductor module
37, 301: base board
40: Y-capacitor
43: X-capacitor
100: DC-to-DC converter
102: interface cable
136: battery
138: DC connector
140: inverter circuit
150: series circuit of upper and lower arms
153, 163: collector electrode
154: gate electrode
155: emitter electrode for signal
156, 166, 913: diode
157: positive electrode terminal
158: negative electrode terminal
159, 320B: AC terminal
164: gate electrode
165: emitter electrode
169: intermediate electrode
172: control circuit
174: driver circuit
180: current sensor
188: AC connector
200: power converter apparatus
300a to 300c: first power semiconductor module
302a to 302c: fin
304: metal base
315B: DC positive electrode terminal
315k, 319k: connection end
319B: DC negative electrode terminal
325L, 325U: signal terminal
328, 330: IGBT
334: insulating substrate
334k: circuit wiring pattern
334r: solid pattern
337a, 337b: solder
350: resin member
371: bonding wire
417, 418, 421, 422, 423: flow direction
500: capacitor module
500a: capacitor element
501: capacitor bus bar
501N: negative electrode bus bar
501M: capacitor bus bar resin
501P: positive electrode bus bar
504: negative electrode side capacitor terminal
504a, 506a: DC bus bar
506: positive electrode side capacitor terminal
508: negative electrode side power supply terminal
509: positive electrode side power supply terminal
510: DC-to-DC terminal
710: first substrate
711: second substrate
802: AC bus bar
850: first recessed section
850a, 851a, 851b: wall
851: second recessed section
904: first lateral surface cover
905: second lateral surface cover
910: LV connector
910a: connection terminal
911: choke coil
912: coil
D: arrangement direction
DEF: differential gear
EGN: engine
HEV: hybrid vehicle
MG1: motor generator
TM: transmission
TSM: power dividing mechanism

1. A power converter apparatus comprising:
a power semiconductor module having a power semiconductor element for converting DC current to AC current;
a DC-to-DC converter for converting specified DC voltage to different DC voltage;
a capacitor module for smoothing the DC voltage and supplying the smoothed DC voltage to the power semiconductor module and the DC-to-DC converter;
a flow-path forming body for forming a flow path through which a refrigerant flows;
a case for housing the power semiconductor module, the DC-to-DC converter, the capacitor module, and the flow-path forming body; and
a first DC connector for transmitting the DC current, wherein
the power semiconductor module is arranged in a position facing the DC-to-DC converter with the flow-path forming body being interposed therebetween,
the DC connector is arranged on a specified surface side of the case,
the specified surface of the case is formed along an arrangement direction of the power semiconductor module, the flow-path forming body, and the DC-to-DC converter, and
the capacitor module is arranged between the specified surface of the case and the flow-path forming body and is connected to the DC connector.

2. The power converter apparatus according to claim 1, comprising:
an AC connector for transmitting the AC current; and
a second DC connector for transmitting the different DC voltage, wherein
the AC connector and the second DC connector are arranged on the specified surface side of the case.

3. The power converter apparatus according to claim 1, wherein
the flow path of the flow-path forming body has a first flow path and a second flow path,
the first flow path and the second flow path are aligned in the arrangement direction of the power semiconductor module and the DC-to-DC converter,
the first flow path is arranged closer to the power semiconductor module than the DC-to-DC converter and is arranged to face the power semiconductor module,
the second flow path is arranged closer to the DC-to-DC converter than the power semiconductor module and is formed to face the DC-to-DC converter, and
the capacitor module is arranged to stretch over the first flow path and the second flow path.

4. The power converter apparatus according to claim 3, wherein
the DC-to-DC converter includes:
a switching element on a high voltage side that is connected to a high-voltage power supply side;
a semiconductor element on a low voltage side that is connected to a low-voltage power supply side;
a transformer circuit; and
a base board that has the switching element on the high voltage side, the semiconductor element on the low voltage side, and the transformer circuit mounted thereon,
the base board is connected to the flow-path forming body, and
the switching element on the high voltage side, the semiconductor element on the low voltage side, and the transformer circuit are arranged along the second flow path.

5. The power converter apparatus according to claim 1, comprising:
a driver circuit for outputting drive voltage for driving the power semiconductor element; and
a substrate having the driver circuit mounted thereon, wherein
the case has a first recessed section for housing the power semiconductor module,
the first recessed section has a bottom surface formed by the flow-path forming body and a lateral surface partially formed by a wall for housing the capacitor module,
the substrate is arranged in a position facing the bottom surface of the first recessed section with the power semiconductor module being interposed therebetween, and
the substrate is further supported by the wall for housing the capacitor module.

6. The power converter apparatus according to claim 5, comprising:
a control circuit for outputting a control signal to control the driver circuit; and
a signal connector for receiving a signal from the outside, wherein
the substrate further has the control circuit and the signal connector mounted thereon, and
the case is formed with a through hole for penetrating the signal connector on a surface that faces the signal connector.

7. The power converter apparatus according to claim 1, comprising:
a driver circuit for outputting drive voltage to drive the power semiconductor element;
a control circuit for outputting a control signal to control the driver circuit;
a signal connector for receiving a signal from the outside; and
a substrate having the driver circuit, the control circuit, and the signal connector mounted thereon, wherein
the case is formed with a through hole for penetrating the signal connector on a surface that faces the signal connector.

8. The power converter apparatus according to claim 5, wherein
the case is formed with a second recessed section for housing the capacitor module,
the second recessed section has a bottom surface formed by the flow-path forming body, and
the first recessed section and the second recessed section have different depths from each other.
